(19) United States
(12) Patent Application Publication
(10) Pub. No.: US 2012/0085941 A1
(43) Pub. Date: Apr. 12, 2012

(54) ION IMPLANTATION APPARATUS AND METHOD

(75) Inventor: Takeshi SHIBATA, Mie (JP)

(73) Assignee: KABUSHIKI KAISHA TOSHIBA, Tokyo (JP)

(21) Appl. No.: 13/268,118

(22) Filed: Oct. 7, 2011

(30) Foreign Application Priority Data
Oct. 8, 2010 (JP) 2010-228843

(51) Int. Cl. H01J 37/317

(52) U.S. Cl. 250/492.21

(57) ABSTRACT

According to one embodiment, a material gas led into a vacuum container is ionized. When ions are implanted into a semiconductor substrate, gas is exhausted from the vacuum container by a pump and the gas exhausted by the pump is returned to the vacuum container and reused. This makes it possible efficiently use the material gas.

### CROSS-REFERENCE TO RELATED APPLICATIONS

This application is based upon and claims the benefit of priority from Japanese Patent Application No. 2010-228843, filed on Oct. 8, 2010; the entire contents of which are incorporated herein by reference.

### FIELD

Embodiments described herein relate generally to an ion implantation technology in semiconductor manufacturing.

### BACKGROUND

An ion implantation apparatus used for manufacturing of a semiconductor product decomposes and ionizes a material gas of ions to be implanted, selects ionized particles having a required quantity and energy out of particles of the ionized material gas, and accelerates and irradiates the selected ionized particles on a substrate wafer.

### BRIEF DESCRIPTION OF THE DRAWINGS

FIG. 1 is a schematic diagram of an entire ion implantation apparatus according to a first embodiment;

FIG. 2 is a schematic diagram of the configuration of an exhaust section of an ion source chamber of an ion implantation apparatus shown as a comparative example;

FIG. 3 is a schematic diagram of the configuration of an exhaust section of an ion source chamber of the ion implantation apparatus according to the first embodiment;

FIG. 4 is a graph of a temporal change of an amount of gas in an arc chamber; and

FIG. 5 is a schematic diagram of the configuration of an exhaust section of an ion source chamber of an ion implantation apparatus according to a second embodiment.

### DETAILED DESCRIPTION

In general, according to one embodiment, a material gas is supplied into a vacuum container, the supplied material gas is ionized, and ions are implanted into a semiconductor substrate. Gas in the vacuum container is exhausted by a pump. A part of the gas exhausted by the pump is discarded. The remainder of the gas is returned to the vacuum container via a circulating gas channel.

Exemplary embodiments of an ion implantation apparatus will be explained below in detail with reference to the accompanying drawings. The present invention is not limited to the following embodiments.

### First Embodiment

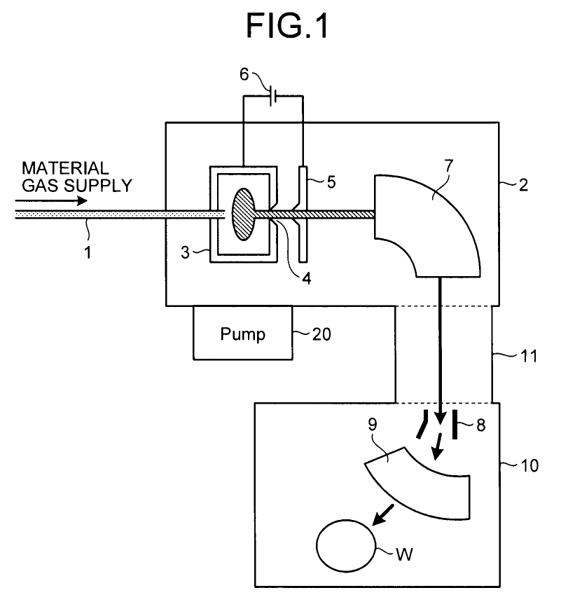

FIG. 1 is a schematic diagram of an entire ion implantation apparatus according to a first embodiment. In FIG. 1, a material gas of ions that should be implanted (in general, any one of boron trifluoride BF3, phosphine PH3, arsine AsH3, and the like) is led into an arc chamber 3 in an ion source chamber 2, which serves as a vacuum container, via a gas supply channel 1 at a flow rate defined in a processing recipe. In the arc chamber 3, thermal electrons generated from a filament are accelerated by an arc voltage and the thermal electrons are caused to collide with the material gas led into the arc chamber 3 to perform decomposition/ionization (conversion into plasma) of the material gas, whereby the ions of the material gas are generated. The arc chamber 3 includes a slit 4 for drawing out the ions. An electric field called draw-out voltage 6 is applied between a draw-out electrode 5 and the arc chamber 3, whereby the ions are drawn out from the arc chamber 3 through the slit 4.

Ionized particles are drawn out by the draw-out voltage 6 and accelerated to desired energy. Only specific ions having a predetermined mass and energy are selected out of the accelerated ions by a mass spectrometry magnet 7. A specific ion beam selected by the mass spectrometry magnet 7 passes through an ion transport system 11 and is scanned according to the size of a wafer W by a scanner 8 in a process chamber 10. Further, after being converted into parallel beams by a collimator magnet 9, the ion beam is irradiated on the substrate wafer W, which serves as a semiconductor substrate. In some case, the order (a combination) of the acceleration (deceleration) of the ions and the mass spectrometry is different depending on target energy or the like. For example, there is an apparatus that, after drawing out the ions from the arc chamber 3, first, accelerates the ions to about 30 kilovolts and performs the mass spectrometry and then accelerates the ions again to target energy (e.g., 200 kilovolts) or decelerate the ions to low energy.

The material gas led into the arc chamber 3 is drawn out as ions or freely diffuses into the ion source chamber 2 having a high degree of vacuum from the slit 4 in a state of neutral gas particles (molecules/radical molecules/atoms). During processing, a fixed amount of the material gas is supplied to always keep a fixed draw-out current amount.

Atoms drawn out as ions among target atoms included in the material gas led into the arc chamber 3 are, in general, about 10% to 20%. The remainder diffuse into the ion source chamber 2 as radical molecules after decomposition/decomposed and recombined separate molecules and are exhausted by a pump 20 attached to the ion source chamber 2. In some case, a part of the molecules diffuse from the ion source chamber 2 to the ion transport system 11 and the process chamber 10. However, a percentage of such molecules in all the molecules is small. Most of the molecules are exhausted from the ion source chamber 2 by the pump 20.

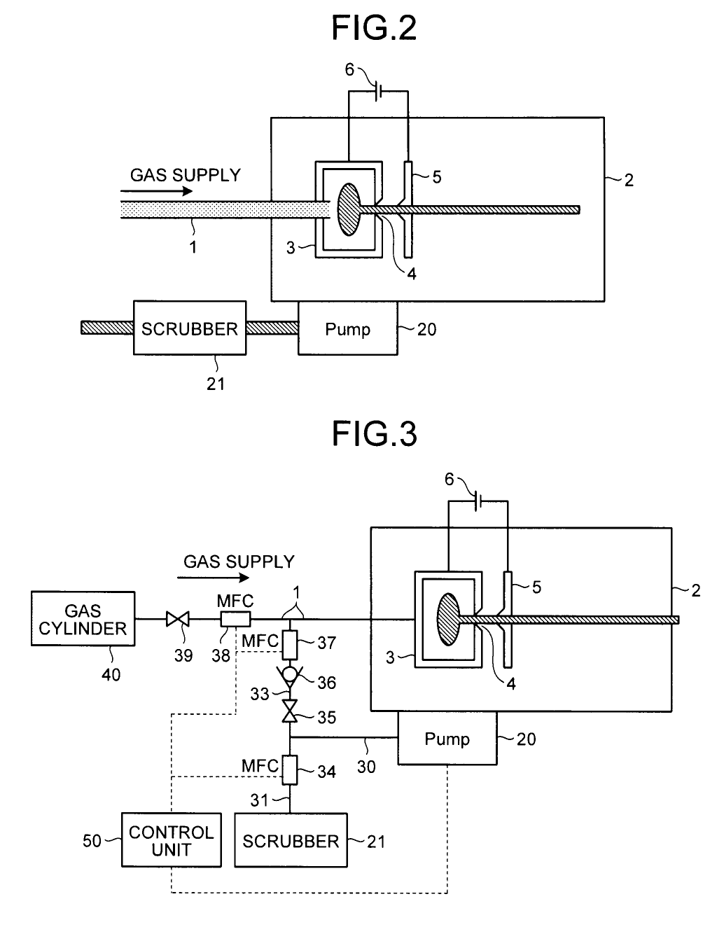

FIG. 2 is a diagram of the configuration of an exhaust section of the ion source chamber 2 of an ion implantation apparatus shown as a comparative example. In this comparative example, a fixed amount of a material gas is steadily supplied to the ion source chamber 2. All of the material gas and a by-product of the material gas (radical molecules after decomposition, decomposed and recombined separate molecules, etc.) discharged from the ion source chamber 2 by the pump 20 are emitted to the atmosphere after being detoxicated through a scrubber 21.

As explained above, in the comparative example, 80% to 90% of the material gas led into the ion source chamber 2 is discarded without being used. Therefore, it is necessary to lead the material gas five to ten times as much as a truly necessary amount into the apparatus. This causes an increase in ion implantation processing cost. The exhaust gas cannot be emitted to the atmosphere unless the exhaust gas is detoxicated through the scrubber once. Because a larger amount of the material gas is led in and discarded, more facility expenses and running costs are required to detoxicate the exhaust gas.

Therefore, taking notice of the fact that the material gas and the by-product of the material gas are included in the gas discharged from the pump 20 and could be an ion source of gas ionized in the arc chamber 3, the ion implantation apparatus according to this embodiment leads the exhaust gas exhausted from the arc chamber 3 by the pump 2 into the arc chamber 3 again and reused as an ion source gas.

FIG. 3 is a diagram of a configuration example of a gas circulating system according to the first embodiment. In FIG. 3, a gas cylinder 40 filled up with the material gas (in general, any one of boron trifluoride BF3, phosphine PH3, arsine AsH3, and the like) is connected to one end of the gas supply channel 1. The other end of the gas supply channel 1 is connected to the arc chamber 3 of the ion source chamber 2. An on-off valve 39 and a mass flow controller (hereinafter abbreviated as “MFC”) 38, which functions as a flow control valve, are arranged along the gas supply channel 1. The MFC 38 is provided on an upstream side of a joining position of the gas supply channel 1 and a circulating gas channel 33. A gas channel 30 on an exhaust side of the pump 20, which is a dry pump, is divided into two halfway. The discarded gas channel 31 is connected to one side of divided two channels. The circulating gas channel 33 is connected to the other side of the divided two channels.

The discarded gas channel 31 is connected to the scrubber 21. An MFC 34 is provided along the discarded gas channel 31. The circulating gas channel 33 is joined to the gas supply channel 1. An on-off valve 35, a check valve 36, and an MFC 37 are provided along the circulating gas channel 33. A control unit 50 executes discharge flow rate control for the pump 20, flow rate control for the MFCs 34, 37, and 38, on-off control for the on-off valves 35 and 39, and the like.

In such a configuration, the check valve 36 that checks a gas flow from the gas supply channel 1 side to the on-off valve 35 side and receives only a gas flow from the on-off valve 35 side to the gas supply channel 1 side is provided in the circulating gas channel 33. The control unit 50 executes control of a ratio of gas reused according a requested draw-out current amount, i.e., flow rate distribution control for gas exhausted from the arc chamber 3 by the pump 20 and divided into two. In other words, the control unit 50 adjusts target flow rate values set in the MFCs 34 and 37 to thereby adjust a distribution of a flow rate of the gas emitted to the atmosphere through the scrubber 21 and a flow rate of the gas circulated to the gas supply channel 1. Further, the control unit 50 executes flow rate distribution control for the joined gas, i.e., adjusts, according to target flow rate values set in the MFCs 38, and 37, a flow rate distribution of a flow rate of the gas flowing through the gas supply channel 1 before the joining and a flow rate of the gas flowing through the circulating gas channel 33.

Therefore, a part of the material gas and the by-product of the material gas exhausted from the arc chamber 3 by the pump 20 are collected in the scrubber 21 through the gas channel 30, the MFC 34, and the discarded gas channel 31 and emitted to the atmosphere after being detoxicated by the scrubber 21. On the other hand, the remainder of the material gas and the by-product of the material gas exhausted from the arc chamber 3 by the pump 20 are joined to the gas supply channel 1 through the on-off valve 35, the check valve 36, and the MFC 37 of the circulating gas channel 33. Consequently, a part of the material gas supplied from the gas cylinder 40 and the gas exhausted by the pump 20 are supplied to the arc chamber 3 of the ion source chamber 2 through the gas supply channel 1.

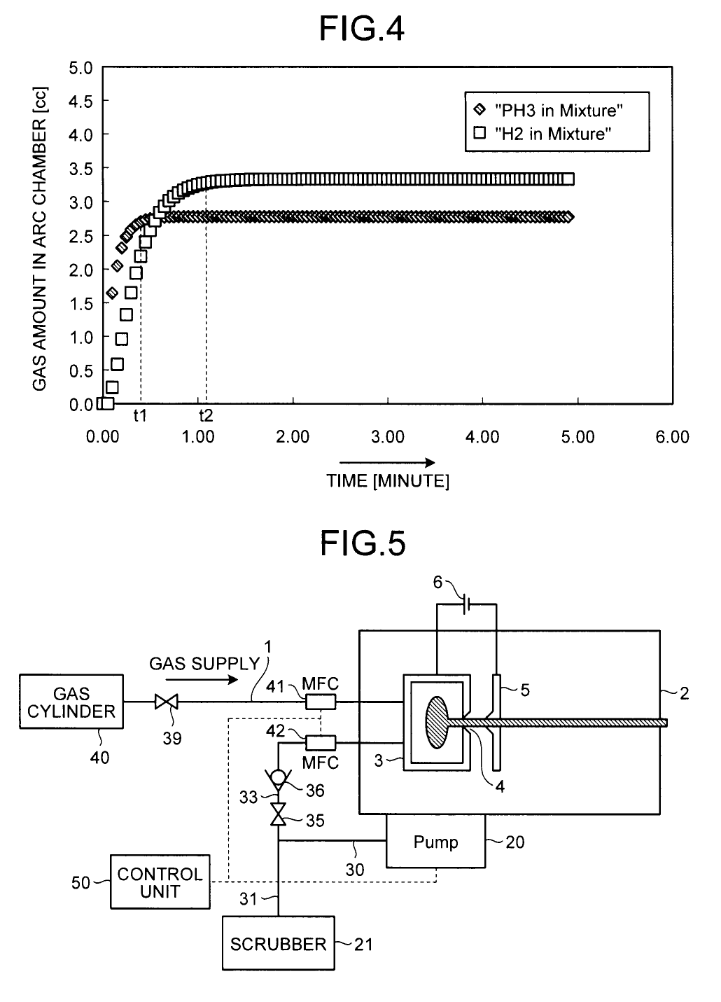

FIG. 4 is a graph of a temporal change of an amount of gas (gas pressure) in the arc chamber 3 in the embodiment shown in FIG. 3. In FIG. 4, 100% phosphine PH3 is adopted as the material gas and 20% P is consumed as an ion source. In this case, a material gas at a flow rate of 1.0 sccm is supplied from the gas chamber 40. An amount of phosphorous atoms in terms of phosphine molecules PH3 is shown. In FIG. 4, larger white squares indicate an amount of gas of PH3 and smaller hatched squares indicate an amount of hydrogen atoms in terms of hydrogen molecules H2. When the phosphine PH3 is adopted as the material gas, the gas exhausted from the arc chamber 3 by the pump 20 includes PH, PH3, P, P2H4, and the like. Specifically, PH3 reacting in the arc chamber 3 is decomposed, P radicals, PH radicals, PH2 radicals, H radicals, and the like are generated. When the P radicals, the PH radicals, the PH2 radicals, the H radicals, and the like are combined, PH, PH3, P, P2H4, and the like, which are neutral molecules, are exhausted.

Because it is an object of the ion implantation apparatus to extract target ions, even if gas once reacts, if the gas includes desired elements, the gas can be supplied to the arc chamber 3 again and used as a source gas. When all the gas exhausted by the pump 20 is circulated to the arc chamber 3 without being discarded, hydrogen is not consumed in the arc chamber 3. Therefore, a percentage of P atoms in the gas supplied into the arc chamber 3 decreases as the circulation is furthered. On the other hand, when a part of the gas exhausted by the pump 20 is discarded and the remainder is circulated, a discharge flow rate of the pump 20 and flow rates of the MFCs 34, 37, and 38 in the arc chamber 3 are adjusted by the control unit 50, whereby it is possible to maintain an amount of gas in the arc chamber 3 at a fixed value, i.e., in a steady state after a certain degree of time elapses. In FIG. 4, as an example, 20% of the gas exhausted from the pump 20 is discarded and the remainder is supplied to the arc chamber 3 again. After time t1, an amount of phosphorous atoms in terms of PH3 in the arc chamber 3 is maintained in a steady state. Similarly, an amount of hydrogen atoms in terms of H2 in the arc chamber 3 can also be maintained at a fixed value, i.e., in a steady state after a certain degree of time elapses. In FIG. 4, after time t2, the amount of hydrogen atoms in terms of H2 in the arc chamber 3 is maintained in the steady state.

As explained above, according to this embodiment, a part of the material gas and the by-product of the material gas exhausted from the arc chamber 3 by the pump 20 are joined to the gas supply channel 1 and circulated to the arc chamber 3 through the circulating gas channel 33 to reuse the material gas exhausted from the arc chamber 3. Because it is an object of the ion implantation apparatus to extract target ions, even if gas once reacts and includes a plurality of different molecules, if the gas includes desired elements, the gas can be supplied to the arc chamber 3 again and used as a source gas. Consequently, it is possible to efficiently use the material gas and reduce a supply amount of the material gas. Further, because a discarding amount of the material gas is reduced, it is possible to reduce a load of the scrubber and reduce cost of a semiconductor product.

### Second Embodiment

FIG. 5 is a diagram of a configuration example of a gas circulating system according to a second embodiment. The gas circulating system according to the second embodiment circulates a part of a material gas and a by-product of the material gas exhausted from the pump 20 are directly circulated to the arc chamber 3 of the ion source chamber 2.

In the second embodiment, as in the first embodiment, a part of the material gas and the by-product of the material gas exhausted from the arc chamber 3 by the pump 20 are collected in the scrubber 21 through the gas channel 30 and the discarded gas channel 31 and emitted to the atmosphere after being detoxicated by the scrubber 21. On the other hand, the remainder of the material gas and the by-product of the material gas exhausted from the arc chamber 3 by the pump 20 are directly circulated to the arc chamber 3 through the on-off valve 35, the check valve 36, and an MFC 42 of the circulating gas channel 33. Therefore, the material gas supplied from the gas cylinder 40 through the gas supply channel 1 and the material gas for reuse circulated through the circulating gas channel 33 are supplied to the arc chamber 3. The check valve 36 checks a gas flow from the arc chamber 3.

In the second embodiment, as in the first embodiment, a discharge flow rate of the pump 20 and flow rates of an MFC 41 provided in the gas supply channel 1 and the MFC 42 provided in the circulating gas channel 33 are properly controlled by the control unit 50. Therefore, it is possible to maintain an amount of phosphorous atoms and an amount of hydrogen atoms in the arc chamber 3 at fixed values, i.e., in a steady state after a certain degree of time elapses.

The present invention can also be applied to an ion implantation apparatus employing a plasma doping method. In the ion implantation apparatus employing the plasma doping method, a sample table subjected to potential control is set in a vacuum container. The ion implantation apparatus supplies a doping material gas into the vacuum container and decompresses the inside of the vacuum container with a pump to keep the inside of the vacuum container at fixed pressure. The ion implantation apparatus forms plasma in the vacuum container with a plasma source and applies a high-voltage pulse to the sample table to attract ions in the plasma to a wafer on the sample table and implant the ion into the wafer. In such an ion implantation apparatus employing the plasma doping method, this embodiment can be applied to discard a part of the material gas discharged by the pump and return the remainder into the vacuum container.

In the present invention, as the material gas, a high-pressure gas obtained by diluting the material gas with a dilution gas can be used. When phosphine PH3 is adopted as the material gas, hydrogen gas H2 is adopted as the dilution gas. Further, in the present invention, the material gas can be supplied from an SDS (safe delivery source) gas cylinder to the arc chamber 3. In the SDS gas cylinder, an absorbent that absorbs a gas component is filled on the inside of a cylinder. Gas of an ion source is captured into the absorbent and pressure lower than the atmospheric pressure is maintained. In an SDS cylinder system, gas is supplied according to a pressure difference between internal pressure of the SDS cylinder and high vacuum in the ion source chamber 2.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An ion implantation apparatus that ionizes a material gas supplied into a vacuum container and implants ions into a semiconductor substrate, the ion implantation apparatus comprising:
a gas supply path for supplying the material gas to the vacuum container;
a pump that exhausts gas from the vacuum container;
a circulating gas channel that can return the gas exhausted by the pump to the vacuum container; and
a discarded gas channel that can discard a part of the gas exhausted by the pump.

2. The ion implantation apparatus according to claim 1, wherein
the gas exhausted by the pump includes the material gas and a by-product of the material gas, and
the material gas and the by-product of the material gas can be an ion source of the gas to be ionized.

3. The ion implantation apparatus according to claim 1, wherein the vacuum container is an ion source chamber that houses an arc chamber into which the material gas is led and in which the material gas is ionized.

4. The ion implantation apparatus according to claim 1, wherein a scrubber that detoxicates a part of the gas exhausted by the pump and emits the part of the gas to atmosphere is provided in the discarded gas channel.

5. The ion implantation apparatus according to claim 1, wherein the circulating gas channel is divided from the discarded gas channel.

6. The ion implantation apparatus according to claim 1, wherein the circulating gas channel joins the gas exhausted by the pump to the gas supply path.

7. The ion implantation apparatus according to claim 6, wherein a check valve that checks a gas flow from the gas supply path is provided in the circulating gas channel.

8. The ion implantation apparatus according to claim 1, wherein the circulating gas channel directly returns the gas exhausted by the pump to the vacuum container.

9. The ion implantation apparatus according to claim 8, wherein a check valve that checks a gas flow from the vacuum container is provided in the circulating gas channel.

10. The ion implantation apparatus according to claim 7, wherein flow-rate control valves are respectively provided on an upstream side of a section of the joining in the gas supply path, in the circulating gas channel, and in the discarded gas channel.

11. The ion implantation apparatus according to claim 9, wherein flow-rate control valves are respectively provided in the gas supply path and the circulating gas channel.

12. The ion implantation apparatus according to claim 10, further comprising a control unit that controls a suction flow rate of the pump and a plurality of the flow-rate control valves to control an amount of the material gas in the vacuum container to be in a steady state.

13. The ion implantation apparatus according to claim 11, further comprising a control unit that controls a suction flow rate of the pump and a plurality of the flow-rate control valves to control an amount of the material gas in the vacuum container to be in a steady state.

14. An ion implantation method for ionizing a material gas supplied into a vacuum container and implanting ions into a semiconductor substrate, the ion implantation method comprising:
exhausting gas from the vacuum container with a pump; and
returning the gas exhausted by the pump to the vacuum container, reusing the gas, and discarding a part of the exhausted gas.

15. The ion implantation method according to claim 13, wherein
the gas exhausted by the pump includes the material gas and a by-product of the material gas, and
the material gas and the by-product of the material gas can be an ion source of the gas to be ionized.

16. The ion implantation method according to claim 14, wherein the vacuum container is an ion source chamber that houses an arc chamber into which the material gas is led and in which the material gas is ionized.

17. The ion implantation method according to claim 14, further comprising detoxicating a part of the gas exhausted by the pump and emitting the part of the gas to atmosphere.

18. The ion implantation method according to claim 14, further comprising controlling a suction flow rate of the pump and flow rates of the material gas supplied to the vacuum container and the gas returned to the vacuum container to control an amount of the material gas in the vacuum container to be in a steady state.

19. The ion implantation method according to claim 15, further comprising controlling a suction flow rate of the pump and flow rates of the material gas supplied to the vacuum container and the gas returned to the vacuum container to control an amount of the material gas in the vacuum container to be in a steady state.

20. The ion implantation method according to claim 16, further comprising controlling a suction flow rate of the pump and flow rates of the material gas supplied to the vacuum container and the gas returned to the vacuum container to control an amount of the material gas in the vacuum container to be in a steady state.
